(19) United States
(12) Patent Application Publication
(10) Pub. No.: US 2025/0096339 A1
(43) Pub. Date: Mar. 20, 2025

(54) SYSTEM AND METHOD FOR ASSESSING A BATTERY MODULE

(71) Applicant: GM Global Technology Operations LLC, Detroit, MI (US)

(72) Inventors: Chinmaya Patil, South Lyon, MI (US); Jun-mo Kang, Ann Arbor, MI (US)

(73) Assignee: GM GLOBAL TECHNOLOGY OPERATIONS LLC, Detroit, MI (US)

(21) Appl. No.: 18/467,997

(22) Filed: Sep. 15, 2023

(51) Int. Cl. H01M 10/48; G01R 31/392; G06T 7/00; G06T 7/277

(52) U.S. Cl. CPC H01M 10/482; G01R 31/392; G06T 7/0004; G06T 7/277; G06T 2207/30152

(57) ABSTRACT

A method that includes performing a battery module functionality test on battery cell arrays within the battery module to obtain battery test data for each of the battery cell arrays. The battery test data is used to determine if a measured parameter for one of the battery cell arrays deviates from a predetermined threshold for the measured parameter. A focused secondary battery test is performed on each of the battery cell arrays having the measured parameter that deviates from the predetermined threshold. The battery module is then qualified based on at least one of the battery test data and the focused secondary battery test.

### INTRODUCTION

The present disclosure relates to systems and methods for detecting defects in battery modules.

A battery or battery module (e.g., a rechargeable battery for electric and/or hybrid electric vehicles) may include individual battery cells. Types of rechargeable batteries include, but are not limited to, lithium ion, lithium-sulfur (Li—S), lithium metal, and/or other types of rechargeable batteries. The battery cells may be assembled into battery modules. The individual battery cells in the battery module are typically arranged into battery cell arrays with battery cells connected in parallel through bus bars. The individual battery cell arrays are then connected to each other in series. The bus bars can be connected to the battery cells through a welding process, such as laser welding.

### SUMMARY

Disclosed herein is a method of assessing a battery module. The method includes performing a battery module functionality test on battery cell arrays within the battery module to obtain battery test data for each of the battery cell arrays. The battery test data is used to determine if a measured parameter for one of the battery cell arrays deviates from a predetermined threshold for the measured parameter. A focused secondary battery test is performed on each of the battery cell arrays having the measured parameter that deviates from the predetermined threshold. The battery module is then qualified based on at least one of the battery test data and the focused secondary battery test.

Another aspect of the disclosure may include forming each of the battery cell arrays by welding battery cells to at least one corresponding bus bar.

Another aspect of the disclosure may be where the battery cell arrays each include battery cells welded to the at least one corresponding bus bar in parallel.

Another aspect of the disclosure may be where the battery module functionality test includes performing a hybrid pulse power characterization test on each of the battery cell arrays in the battery module.

Another aspect of the disclosure may be where the hybrid pulse power characterization test includes applying discharge and charge pulses on each of the battery cell arrays in the battery module.

Another aspect of the disclosure may be where determining if the measured parameter for one of the battery cell arrays deviates from the predetermined threshold includes performing a statistical analysis to determine if the measured parameter for one of the battery cell arrays is an outlier compared to the measured parameter for a remainder of the battery cell arrays.

Another aspect of the disclosure may be where the outlier is determined based on performing a statical analysis on the battery test data for each of the battery cell arrays.

Another aspect of the disclosure may be where the statistical analysis includes performing a principal component analysis based on the measured parameter from the battery test data.

Another aspect of the disclosure may include tracking the measured parameter from the battery module functionality test with a Kalman filter.

Another aspect of the disclosure may include identifying a tracking trace of the measured parameter and performing the principal component analysis on the tracking trace of the measured parameter.

Another aspect of the disclosure may be where the predetermined threshold includes a predetermined range of values for the measured parameter.

Another aspect of the disclosure may be where obtaining battery test data includes performing a direct current internal resistance test on each of the battery cell arrays.

Another aspect of the disclosure may be where obtaining battery test data includes measuring a voltage across each of the battery cell arrays.

Another aspect of the disclosure may be where the focused secondary test includes performing a flash thermography by applying a flash of light to a target area including one of the battery cell arrays with the measured parameter that deviates from the predetermined threshold and capturing at least one image of the target area with an imaging camera to assess a welds in the target area.

Another aspect of the disclosure may be where the secondary test includes directing at least one of an optical sensor or an ultrasound at the target area.

Disclosed herein is a non-transitory computer-readable storage medium embodying programmed instructions which, when executed by a processor, are operable for performing a method. The method includes performing a battery module functionality test on battery cell arrays within the battery module to obtain battery test data for each of the battery cell arrays. The battery test data is used to determine if a measured parameter for one of the battery cell arrays deviates from a predetermined threshold for the measured parameter. A focused secondary battery test is performed on each of the battery cell arrays having the measured parameter that deviates from the predetermined threshold. The battery module is then qualified based on at least one of the battery test data and the focused secondary battery test.

Disclosed herein is a system for assessing a battery module. The system includes a battery module having battery cell arrays and a secondary battery test device configured to be directed at the battery module. A controller is in communication with the battery module and the secondary battery test device. The controller is configured to perform a battery module functionality test on the battery cell arrays within the battery module to obtain battery test data for each of the battery cell arrays and determine from the battery test data if a measured parameter for one of the battery cell arrays deviates from a predetermined threshold for the measured parameter. The controller is also configured to perform a focused secondary battery test on each of the battery cell arrays that include the measured parameter that deviates from the predetermined threshold and qualify the battery module based on at least one of the battery test data and the focused secondary battery test.

### BRIEF DESCRIPTION OF THE DRAWINGS

FIG. 1 illustrates an assembly for creating a battery module.

FIG. 2 illustrates a method of assessing the battery module.

FIG. 3A graphically illustrates a first example measured parameter for each of a plurality of battery cell arrays in the battery module.

FIG. 3B graphically illustrates a second example measured parameter for each of a plurality of battery cell arrays in the battery module.

FIG. 3C graphically illustrates a third example measured parameter for each of a plurality of battery cell arrays in the battery module.

FIG. 3D graphically illustrates a fourth example measured parameter for each of a plurality of battery cell arrays in the battery module.

FIG. 4 graphically illustrates a set of modal coefficients.

### DETAILED DESCRIPTION

The components of the disclosed embodiments, as described and illustrated herein, may be arranged, and designed in a variety of different configurations. Thus, the following detailed description is not intended to limit the scope of the disclosure, as claimed, but is merely representative of possible embodiments thereof. In addition, while numerous specific details are set forth in the following description in order to provide a thorough understanding of the embodiments disclosed herein, some embodiments can be practiced without some of these details. Moreover, for the purpose of clarity, certain technical material that is understood in the related art has not been described in detail in order to avoid unnecessarily obscuring the disclosure. Furthermore, the disclosure, as illustrated and described herein, may be practiced in the absence of an element that is not specifically disclosed herein.

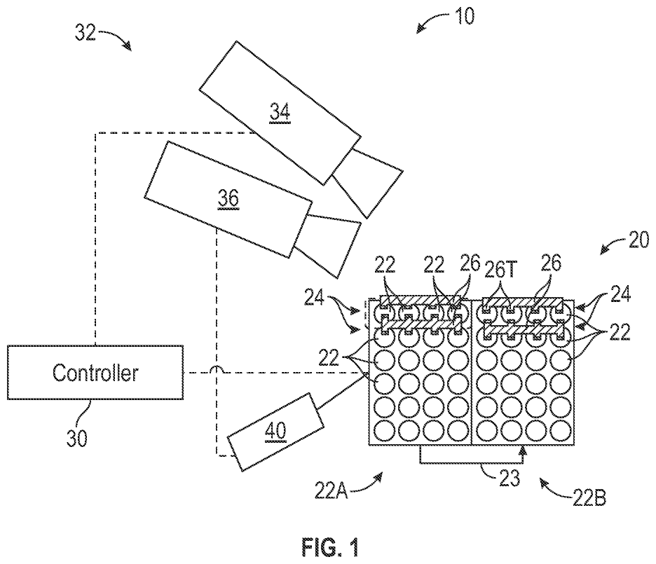

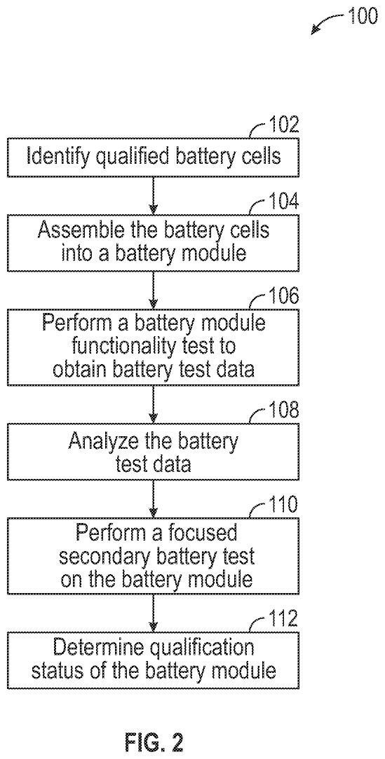

Referring to the drawings, wherein like reference numerals correspond to like or similar components throughout the several Figures, FIG. 1, consistent with embodiments disclosed herein, illustrates an example system 10 for assessing a battery module 20, such as assessing welds formed during assembly of individual battery cells 22 to form the battery module 20. The battery module 20 can be used for powering a machine, such as a vehicle, an electric cart, or a stationary electric device. The individual battery cells 22 in the battery module 20 are arranged into battery cell arrays 24. The battery cell arrays 24 include a group of battery cells 22 connected in parallel to each other through bus bars 26. The bus bars 26 are connected to one of an anode or a cathode of the battery cell 22.

As shown in FIG. 1, a welder 40, such as a laser welder, is used to weld tabs 26T on the bus bars 26 to a corresponding anode or cathode on the battery cell 22 in each battery cell array 24. Although the illustrated example shows two pairs of bus bars 26, the adjacent battery cell arrays 24 in a first bank 22A and a second bank 22B in the battery module 20 are connected in series. Also, an electrical connection 23 connects the first and second banks 22A, to each other in series. The number of battery cells 22 in each of the battery cell arrays 24 can vary in addition to the number of battery cell arrays 24 connected to each other in series. In the illustrated example, the battery module 20 includes twelve battery cell arrays 24 with four battery cells 22 each for a total of 48 battery cells 22.

An electronic controller 30 is in electrical communication with the battery module 20, a secondary battery testing device 32, such as a flash thermography device, for performing a focused secondary battery test, and the welder 40. The flash thermography device includes a light source 34 for generating and directing a flash of light at a target area on the battery module 20 and an imaging camera 36 for receiving the light that reflects off the target area on the battery module 20 for assessing weld quality of the battery module 20. The controller 30 is configured to perform a method 100 of assessing the battery module 20 disclosed below, such as performing functionality testing on the battery module 20, obtaining and analyzing battery module test data, and operating the flash thermography device to determine weld quality between the bus bars 26 and the battery cells 22. However, the secondary battery testing device 32 can also include at least one of an ultrasonic testing device or an optical sensor.

The electronic controller 30 may be embodied as one or multiple digital computers or host machines each having one or more processors, read only memory (ROM), random access memory (RAM), electrically-programmable read only memory (EPROM), optical drives, magnetic drives, etc., a high-speed clock, analog-to-digital (A/D) circuitry, digital-to-analog (D/A) circuitry, and input/output (I/O) circuitry, I/O devices, and communication interfaces, as well as signal conditioning and buffer electronics. The computer-readable memory may include non-transitory/tangible medium which participates in providing data or computer-readable instructions. Memory may be non-volatile or volatile. Non-volatile media may include, for example, optical or magnetic disks and other persistent memory. Example volatile media may include dynamic random-access memory (DRAM), which may constitute a main memory. Other examples of embodiments for memory include a flexible disk, hard disk, magnetic tape or other magnetic medium, a CD-ROM, DVD, and/or other optical medium, as well as other possible memory devices such as flash memory.

The electronic controller 30 includes a tangible, non-transitory memory on which computer-executable instructions, including one or more algorithms, are recorded for assessing the battery module 20 as disclosed here. The subject algorithm(s) may specifically include an algorithm configured to assess weld quality in the battery module 20.

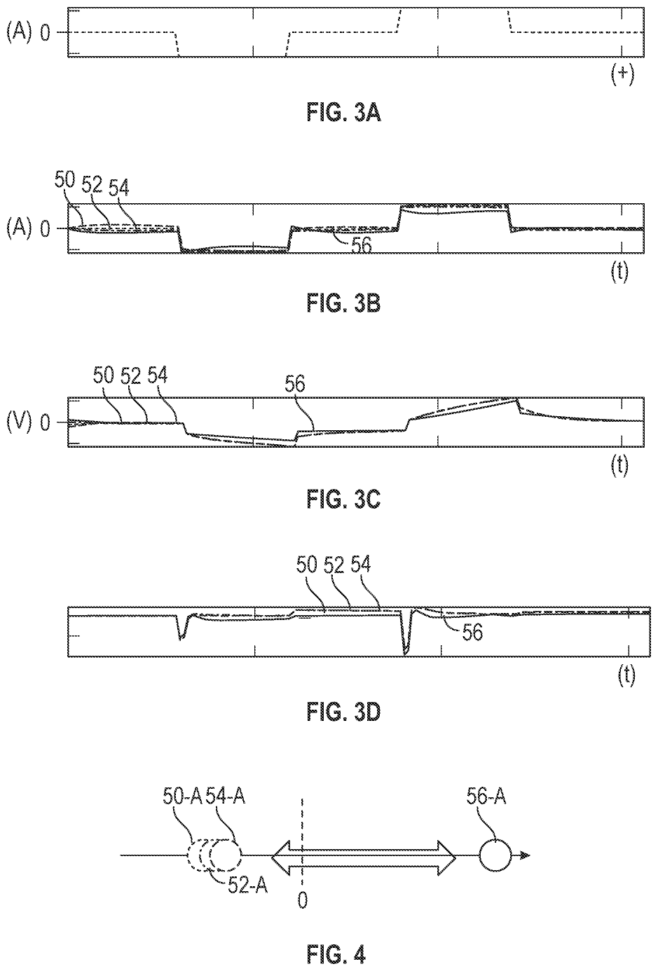

FIG. 3 illustrates a method 100 of assessing quality of the battery module 20. In particular, the method 100 assesses weld quality in the battery module 20, such as welds between the bus bars 26 and each of the battery cells 22. At Block 102, battery cells 22 are qualified based on cell performance or charge level and selected for assembly into one of battery cell arrays 24. The battery cells 22 are qualified based on at least one of performance or cell voltage in order to closely match battery cell characteristics of the battery cells 22 in each battery cell array 24. The battery cell arrays 24 are assembled by welding the battery cells 22 corresponding bus bars 26 with the welder 40 to create the battery cell arrays 24 that form the battery module 20 as described above (Block 104).

Once the battery module is 20 is assembled to include a predetermined number of battery cell arrays 24 connected in series, a battery module functionality test is performed (Block 106). In one example, battery module functionality test includes performing at least one of a direct current internal resistance test on each of the plurality of battery cell arrays 24 or a hybrid pulse power characterization test. The hybrid pulse power characterization test includes performing discharge and charge pulses on each of the plurality of battery cell arrays.

In one example, the controller 30 performs the battery module functionality test and obtains battery test data for each of the battery cell arrays 24 that form the battery module 20. The battery module functionality test can measure at least one of cell current (FIG. 3B) or cell voltage (FIG. 3C) across each of the battery cell arrays 24 for a given load current (FIG. 3A) to obtain a measured parameter.

FIG. 3A illustrates the load current in Amps (A) (vertical axis) over time (t) (horizontal axis). FIG. 3B illustrates the cell current in Amps (A) (vertical axis) in response to the load current from FIG. 3A over time (t) (horizontal axis). In the illustrated example of FIG. 3B, lines 50, 52, 54, and 56 correspond to battery test data for the battery cell arrays 24 in the battery module 20. FIG. 3C illustrates an example cell voltage (V) over time (t). FIG. 3D represents a tracking parameter of internal resistance for each of the battery cell arrays 24 over time (t) (horizontal axis). A multiplying factor of internal resistance can be the tracking parameter of internal resistance.

For simplicity, FIGS. 3A-3D illustrate the results for four battery cell arrays 24. In some instances, the lines 50-56 in FIGS. 3B-3D may collapse on each other and appear as a single line over certain periods of time if all four battery cells are equal.

At Block 108, the method 100 analyzes the battery test data from the battery module functionality test to determine if one of the measured parameters deviates from a predetermined threshold, such as a relative maximum value, minimum value, or range of values. In one example, the analysis includes obtaining a voltage trace, a temperature trace, or another tracking trace, of each of the battery cell arrays 24 from the battery module functionality test. The tracking parameter of internal resistance for each of the battery cell is obtained from the voltage trace of the battery cell using a Kalman filter. The traces of the tracking parameter of internal resistance of the battery cell array 24 are then analyzed by performing a statistical analysis, such as a principal component analysis (PCA). A loose weld bond within the battery module can result in a different trace pattern of tracking parameter of internal resistance.

A PCA is a statistical procedure that converts a set of traces into a set of weighted sum of linearly uncorrelated (orthonormal) traces called principal modes. For a given set of possibly correlated signals or traces, the significant common modes and their contribution to the individual signals can be obtained through PCA.

In one example, the PCA subtracts an average of the individual traces of the tracking parameter of internal resistance from each of the individual traces of the tracking parameter of internal resistance to obtain a difference of each of the individual traces of the tracking parameter of internal resistance from the average. The difference of each of the individual voltage traces of the tracking parameter of internal resistance from the average can then be described through a series of principle modes, such as a first principal mode, a second principal mode, a third principal mode, etc. The coefficients (i.e., weight) of the first principal mode can be graphed to illustrate the health of each of the battery cell arrays 24.

As shown in FIG. 4, the coefficients of the first principal mode each surround zero on the x-axis. However, if a problematic battery cell array 24 exists, the coefficients of the first principal mode for that battery cell array 24 pushes the healthy battery cell arrays 50-A, 52-A, 54-A towards one side and the coefficients for the unhealthy battery cell arrays 56-A towards the other side of a zero value on the graph. This identifies the unhealthy battery cell array 24 as an outlier compared to the healthy battery cell array 24. This occurs because a sum of the coefficients corresponding to each of the battery cell arrays 24 tested will equal zero.

If an unhealthy battery cell array 24 is detected at Block 108, the method 100 performs a focused second battery test, such as a focused flash thermography test, on that battery cell array 24 to assess the quality of the welds on that battery cell array 24 (Block 110). If the battery cell array 24 passes the flash thermography testing for weld quality, the battery module 20 becomes a qualified battery module (Block 112). If the battery cell array 24 fails the flash thermography testing, the battery module 20 can be repaired and qualified again by the method 100 or the battery module 20 becomes rejected.

The terms “a” and “an” do not denote a limitation of quantity, but rather denote the presence of at least one of the referenced item. The term “or” means “and/or” unless clearly indicated otherwise by context. Reference throughout the specification to “an aspect,” means that a particular element (e.g., feature, structure, step, or characteristic) described in connection with the aspect is included in at least one aspect described herein and may or may not be present in other aspects. In addition, it is to be understood that the described elements may be combined in a suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, test standards are the most recent standard in effect as of the filing date of this application, or, if priority is claimed, the filing date of the earliest priority application in which the test standard appears.

Unless defined otherwise, technical, and scientific terms used herein have the same meaning as is commonly understood by one of skill in the art to which this disclosure belongs.

While the above disclosure has been described with reference to exemplary embodiments, it will be understood by those skilled in the art that various changes may be made, and equivalents may be substituted for elements thereof without departing from its scope. In addition, many modifications may be made to adapt a particular situation or material to the teachings of the disclosure without departing from the scope thereof. Therefore, it is intended that the present disclosure is not limited to the particular embodiments disclosed but will include embodiments falling within the scope thereof.

What is claimed is:

1. A method of assessing a battery module, the method comprising:
performing a battery module functionality test on a plurality of battery cell arrays within the battery module to obtain battery test data for each of the plurality of battery cell arrays;
determining from the battery test data if a measured parameter for one of the plurality of battery cell arrays deviates from a predetermined threshold for the measured parameter;
performing a focused secondary battery test on each of the plurality of battery cell arrays that include the measured parameter that deviates from the predetermined threshold; and
qualifying the battery module based on at least one of the battery test data and the focused secondary battery test.

2. The method of claim 1, including forming each of the plurality of battery cell arrays by welding a set of the plurality of battery cells to at least one corresponding bus bar.

3. The method of claim 2, wherein the plurality of battery cell arrays each include a plurality of battery cells welded to the at least one corresponding bus bar in parallel.

4. The method of claim 1, wherein the battery module functionality test includes performing a hybrid pulse power characterization test on each of the plurality of battery cell arrays in the battery module.

5. The method of claim 4, wherein the hybrid pulse power characterization test includes applying discharge and charge pulses on each of the plurality of battery cell arrays in the battery module.

6. The method of claim 1, wherein determining if the measured parameter for one of the plurality of battery cell arrays deviates from the predetermined threshold includes performing a statistical analysis to determine if the measured parameter for one of the plurality of battery cell arrays is an outlier compared to the measured parameter for a remainder of the plurality of battery cell arrays.

7. The method of claim 6, wherein the outlier is determined based on performing a statical analysis on the battery test data for each of the plurality of battery cell arrays.

8. The method of claim 7, wherein the statistical analysis includes performing a principal component analysis based on the measured parameter from the battery test data.

9. The method of claim 8, including tracking the measured parameter from the battery module functionality test with a Kalman filter.

10. The method of claim 9, including identifying a tracking trace of the measured parameter and performing the principal component analysis on the tracking trace of the measured parameter.

11. The method of claim 1, wherein the predetermined threshold includes a predetermined range of values for the measured parameter.

12. The method of claim 1, wherein obtaining the battery test data includes performing a direct current internal resistance test on each of the plurality of battery cell arrays.

13. The method of claim 1, wherein obtaining the battery test data includes measuring a voltage across each of the plurality of battery cell arrays.

14. The method of claim 1, wherein the focused secondary battery test includes performing a flash thermography by applying a flash of light to a target area including one of the plurality of battery cell arrays with the measured parameter that deviates from the predetermined threshold and capturing at least one image of the target area with an imaging camera to assess a plurality of welds in the target area.

15. The method of claim 14, wherein the focused secondary battery test includes directing at least one of an optical sensor or an ultrasound at the target area.

16. A non-transitory computer-readable storage medium embodying programmed instructions which, when executed by a processor, are operable for performing a method comprising:
performing a battery module functionality test on a plurality of battery cell arrays within a battery module to obtain battery test data for each of the plurality of battery cell arrays;
determining from the battery test data if a measured parameter for one of the plurality of battery cell arrays deviates from a predetermined threshold for the measured parameter;
performing a focused secondary battery test on each of the plurality of battery cell arrays that include the measured parameter that deviates from the predetermined threshold; and
qualifying the battery module based on at least one of the battery test data and the focused secondary battery test.

17. The method of claim 16, wherein determining if the measured parameter for one of the plurality of battery cell arrays deviates from the predetermined threshold includes performing a statistical analysis to determine if the measured parameter for one of the plurality of battery cell arrays is an outlier compared to the measured parameter for a remainder of the plurality of battery cell arrays.

18. The method of claim 17, wherein the outlier is determined based on performing a statical analysis on the battery test data for each of the plurality of battery cell arrays.

19. A system for assessing a battery module, the system comprising:
a plurality of battery cell arrays in the battery module;
a secondary battery test device configured to be directed at the battery module;
a controller in communication with the battery module and the secondary battery test device, the controller is configured to:
perform a battery module functionality test on the plurality of battery cell arrays within the battery module to obtain battery test data for each of the plurality of battery cell arrays;
determine from the battery test data if a measured parameter for one of the plurality of battery cell arrays deviates from a predetermined threshold for the measured parameter;
perform a focused secondary battery test on each of the plurality of battery cell arrays that include the measured parameter that deviates from the predetermined threshold; and
qualify the battery module based on at least one of the battery test data and the focused secondary battery test.

20. The system of claim 19, wherein the controller determines if the measured parameter for one of the plurality of battery cell arrays deviates from the predetermined threshold by performing a statistical analysis to determine if the measured parameter for one of the plurality of battery cell arrays is an outlier compared to the measured parameter for a remainder of the plurality of battery cell arrays.
